(19) United States
(12) Patent Application Publication
(10) Pub. No.: US 2023/0336008 A1
(43) Pub. Date: Oct. 19, 2023

(54) BATTERY MANAGEMENT SYSTEM FOR ACCUMULATORS OF A SEMI-MODULAR ELEMENT

(71) Applicant: LIMATECH, TOULOUSE (FR)

(72) Inventors: Luc POUYADOU, BRIGNOUD (FR); Maxime DI MEGLIO, SAINT ORENS (FR); Florence ROBIN, SAINT ORENS (FR)

(21) Appl. No.: 17/928,678

(22) PCT Filed: Jul. 23, 2021
(86) PCT No.: PCT/EP2021/070673

§ 371 Date: Nov. 30, 2022

(30) Foreign Application Priority Data
Jul. 27, 2020 (FR) FR2007907

(51) Int. Cl. H02J 7/00; G01R 31/374; G01R 31/52; G01R 31/3835; G01R 31/396; H01M 10/052; H01M 50/51; H01M 50/583; H01M 50/519; H01M 50/284; H01M 10/6571; H01M 10/48; H01M 10/42

(52) U.S. Cl. CPC H02J 7/00308; G01R 31/374; G01R 31/52; G01R 31/3835; G01R 31/396; H01M 10/052; H01M 50/51; H01M 50/583; H01M 50/519; H01M 50/284; H01M 10/6571; H01M 10/486; H01M 10/482; H01M 10/4264; H02J 7/00304; H02J 7/00306; H01M 2010/4271

(57) ABSTRACT

The present invention relates to a system for managing accumulator batteries (BMS) of a semi-modular element comprising a plurality of lithium cell elements connected in series to form a line, and comprising at least two parallel lines constituting the semi-modular element, and at least one detection circuit characterized in that the detection circuit comprises at least one discharge or short-circuit detection device and at least one device for monitoring the voltage and temperature of at least one, and preferably all, of the cell elements, the detection circuit controlling a circuit breaker device comprising one switching device per line.

### TECHNICAL FIELD OF THE INVENTION

The present invention generally relates to the field of accumulator batteries, in particular lithium accumulator batteries.

### PRIOR ART

Accumulator batteries are made up of electrochemical elements that can be connected in series or in parallel to obtain the necessary voltage and current. A lithium battery that has experienced exceedances of its rated operating parameters may “appear” to be working properly, but present a risk of overheating or fire.

Lithium batteries therefore require protection circuits. Generally, these circuits measure the voltage, current and temperature, and drive a current limiting and switching device.

In the event of a short circuit or overcurrent, it is necessary to disconnect the battery to avoid damaging it and to avoid excessive heating of the battery or its connection cables.

Generally, electromechanical circuit breakers or fuses are used, or electronic circuits that measure the current and control a switching device. However, measuring a current is not simple.

There are several current measurement methods (shunt, magnetic measurement or by thermal effect). However, these may involve high consumption, which may require the use of a “standby” mode and an “active” mode. This is hardly compatible with protection against short circuits, which can occur at any time.

In addition, a heat engine starter battery must supply a very high current for a few seconds to a few tens of seconds. Thus, the current of the circuit breaker must be set to a fairly high value, of the order of half the short-circuit current (the maximum power supplied is reached when the voltage is half of the open-circuit voltage, and the current is half of the short-circuit current).

With aging, or at low temperatures, the internal resistance of battery cells increases, so the short-circuit current decreases. It is possible that this current becomes lower than the tripping current. In this case, the protection is no longer assured. Incorrect use may lead to a complete discharge of the battery in its internal resistor, causing strong overheating, then a fire.

Finally, for example and without limitation, a 17 Ah non-modular battery can supply a short-circuit current of more than 2000 A. Thus, a switching device must be able to withstand this current. Semiconductors that can withstand this current are not common and in practice, several lower-current components are connected in parallel. The balance of the currents is very difficult to achieve, which requires oversizing the components. Measuring a 2000 A current also poses problems of compromise between precision and static consumption.

Several devices have been proposed in order to secure the batteries and in particular to monitor their state, and if necessary, to cause the electronic circuit to be cut off, in particular during short-circuits.

In addition, these systems must thus have a monitoring means and a means of cutting off or opening the circuit. Several different mechanisms exist, with their pros and cons.

Several systems comprise a more or less sophisticated battery management system (BMS) making it possible to track the state of a battery, accumulators of a battery and/or to act on the circuit of the battery to open it in case of problem.

Thus, document EP2092627 proposes a battery management system (BMS) comprising two current inputs and one current output. The document teaches the use of a shunt when the battery is fully charged. The accumulators are arranged in series with a switching device to perform the cut-off in the event of a short circuit. The BMS measures the voltage, the temperature at each accumulator arranged in series. Accumulators can be added one after the other in order to increase the voltage delivered, and the increase in current must be followed by a resizing of the components. The BMS is responsible, at each point, for measuring the balance of each accumulator in order to balance the battery. In other words, there is the equivalent of one BMS per cell. Finally, this document proposes placing a MOSFET (“Charge control”) between the input (+ terminal) and the accumulators, and another MOSFET (“Discharge Control”) between the output (− terminal) and the accumulators.

CN110265738 proposes a different lithium cell array monitoring system, which monitors the temperature, current and voltage of parts of the circuit. It thus allows the detection/protection against overcurrent as well as the limitation of the load current.

The BMS of True Blue Power batteries has a very large number of components, many electronic boards, and many connectors. This penalizes costs and reliability. The BMS has 2 operating modes, “standby and active,” and a brownout is observed every hour in standby mode. The switching device comprises several MOSFETs in parallel. Such a solution involves problems of current balance in the various MOSFETs, requires power components that must be oversized, and finally the current measurement leads to high consumption by the current measuring device and therefore to significant self-discharge.

There are also complex battery management devices like that taught in patent application WO 2018095039 A1, which describes a remote intelligent battery management system, comprising: at least two battery packs, a data analysis center and a terminal monitor. Each battery pack is equipped with a set of lithium batteries, a battery management system (BMS) module, a GPS communication module and a 4G communication module. The BMS module is used to obtain the lithium battery set data and to manage the lithium battery set; the GPS module is used to obtain the location data of the geographical information of the lithium battery pack; the 4G communication module is used to transmit the lithium battery set data and the geographical information location data to the data analysis center by means of a base station; the data analysis center has a data test center, a data storage center and a cloud-based artificial intelligence battery analysis center. The remote intelligent battery management system can adjust a management policy of a BMS in real time and control the charging and discharging conditions of lithium battery sets, such that battery safety is greatly improved. By determining the operating conditions of lithium battery sets, after-sales communication costs are reduced, and the utilization rate and repair rate of lithium battery sets are improved.

In this device, the decision-making and storing member is moved outside the battery. The battery management module only serves to collect the measurements and send them to a data analysis center, which therefore detects anomalies and decides on the management of the batteries.

However, the solutions of the prior art have drawbacks because they provide accumulator batteries that are difficult to modulate while maintaining good balancing of the different accumulators and good reliability and safety. Moreover, the proposed solutions describe architectures using external, even remote, elements, which causes the multiplication of wirings and/or other components rather than a simple architecture internal to the battery.

### DISCLOSURE OF INVENTION

The object of the present invention is therefore to propose a battery management system (BMS) for accumulators for accumulators of a semi-modular element, making it possible to overcome at least some of the drawbacks of the prior art.

This object is achieved by a battery management system (BMS) for accumulators of a semi-modular element comprising a plurality of lithium cell elements (20) connected in series to form a line, said battery management system for accumulators comprising at least two serial lines connected in parallel constituting the semi-modular element, and at least one detection circuit, characterized in that the detection circuit comprises at least one discharge or short-circuit detection device and at least one device for monitoring the voltage and temperature of a cell element, the detection circuit controlling a circuit breaker device comprising at least one switching device per line, preferably only one per line, and connected on the one hand to the negative or positive pole of each set of cell elements or each battery and on the other hand to the positive or negative terminal, respectively, of the battery, the switching device comprising, for each line, a load breaking device, a discharge breaking device, and electronic components limiting the current at the load, preferably only at the load, and said load breaking device comprising at least two, preferably only two, MOSFETs (M1, M2) per line; a first MOSFET (M1) performing a circuit break in the event of discharge below a threshold or during a short circuit, a second MOSFET (M2) performing a load break in the event of voltage or temperature overshoot of an element of said circuit, the electronic components such as a set of diodes, resistors, capacitors, for example around the second MOSFET (M2), performing a current limitation at the load.

According to one feature, the first MOSFET (M1) is connected by its source to the negative terminal of a set of cells, this first MOSFET (M1) receives, on its gate, a voltage source (V2) that drives (M1), this source delivering a chosen voltage (for example 6 to 10 V) so that the first MOSFET (M1) is on, a Zener diode (D3) is connected in opposition between the gate and the source of the first MOSFET (M1) and a capacitor (C2) protect the gate of the first MOSFET (M1) from excessively high or high-frequency voltages, and a Zener diode (D1) mounted in opposition between the gate of the first MOSFET (M1) and the drain and in series with a resistor (R3) and a diode (D2) in the forward direction in the drain-to-gate direction, (D1, D2, R3) limiting the switching speed of the first MOSFET (M1) and a circuit consisting of a Schottky diode (D4) limits the load current, this Schottky diode (D4) is mounted in opposition on the drain of the first MOSFET (M1) in the charging direction, and in series with a capacitor C1 and a resistor R1 connected to the positive terminal of the battery to also limit the overvoltage when opening the first MOSFET M1, in parallel on the Schottky diode (D4) a fixed resistor I1 is mounted that is connected on the one hand to the cathode of the diode and on the other hand to the drain of the second MOSFET (M2) whose source is connected to the anode of the Schottky diode (D4), the gate of the second MOSFET (M2) being controlled by an output of the detection circuit to prevent the load.

According to another feature, the second MOSFET M2 is connected by its gate to the base of the phototransistor of an optocoupler whose emitter is connected to the source of M2; between these two points, a Zener diode D5 and a capacitor C5 are connected by the BMS card; the light-emitting diode of the optocoupler is connected by its cathode to the negative terminal of the battery or of the modular set of cells and receives, on its anode, the command sending a current into the LED in case of detected voltage or temperature overshoot of an element

According to another feature, the arrangement of the disconnection circuit associated with the two MOSFETs is interposed between the output pole of a line and the same terminal, of the same polarity (positive or negative), of the battery.

According to another feature, the BMS is connected to and controls each cell element and each accumulator line of the circuit.

According to another feature, the detection circuit comprises one or more of the following functionalities:
Cell voltage balancing;
Detection of excessively low voltage and open circuit
Detection, by a voltage measurement circuit, of short-circuit, deep discharge and overcurrent to trigger the disconnection of a group of cells by opening the circuit
Detection of excessively high voltage of one of the battery cells and opening of the circuit

According to another feature, the voltage balancing is performed by a diode OR function connecting each of the cells connected in parallel with the negative polarity of the divider bridge of the short-circuit, deep discharge and overcurrent voltage measurement circuit.

According to another feature, each cell element of a line is connected to each adjacent cell element of another line by an element constituting a thermal fuse, preferably resettable. A resistor can act as a fuse.

According to another feature, the detection circuit comprises the following functionalities: integrates temperature monitoring that remains constantly active, even if the battery is “off,” by analyzing the temperature in the battery envelope, measured by a probe mounted on the central part of the cards of each module.

According to another feature, the electronic components of the circuit breaker device limiting the current to the load, preferably only to the load, for regulating the load current comprise a component such as a resistor, which is conductive in one direction, and resistive, like a diode connected in opposition, in the other direction.

According to another feature, the circuit is arranged in such a way that the charging and discharging switching devices are controlled independently.

The present invention also relates to a high-current, semi-modular, series and parallel battery pack consisting of lithium accumulator cells of the same characteristics connected in series to form a line by connections in a given direction S corresponding to the direction of the high currents to obtain the necessary voltage, and intended to be able to be associated in parallel with another line of accumulator cells, said pack using a management system as described in this description, and comprising:
a pair of upper and lower bezels that delimit a set of cylindrical housings with a square or polygonal or circular section defining, in the same direction S, at least one line of cylindrical housings with a square or polygonal section each holding a lithium accumulator cell;
the connections between the accumulator cells of the same line in the direction S are ensured by wide tongues connecting, on each upper or lower face of the module, each pair of adjacent cells connected in series by their poles of opposite polarity in the first direction S, the connecting tongues on one face being offset by one cell on the other face;
the bezels comprise at least two lines of housings parallel to the direction S in which at least two lines of cells are arranged in a direction perpendicular to S and interconnected either by thin tongues acting as a fuse or by resettable fuses, in the direction P perpendicular to the direction S, each fuse connecting two cells belonging to two different parallel lines to make a parallel connection between each cell of two parallel sets of serial cells. A resistor can act as a fuse.

According to one feature, the bezels hold PCBs (printed circuit boards) by the sides at the upper and lower part, which PCBs comprise the electronics and the electrical connections between the electronic components of the management system and the cells of the semi-modular block;
intermediate PCBs are arranged vertically between the cells in a direction perpendicular to the direction S comprise the heating resistors of the semi-modular assembly and these resistors are connected on demand from the management circuit to a power supply;
the PCB part arranged under the cells contributes to recovering the potentials of each of the cells of the modular block to supply them to the voltage management and balancing circuit of the modular block management system.

According to another feature, resistors are mounted between two contact pads (not shown) on the upper and/or lower PCBs and the contact with the cells and the tracks of the upper or lower printed circuit boards are made by elastic pins (Pogo or conical coil springs, for example) arranged between the cells and the conductive face comprising the contact pads of the printed circuit board, thus avoiding the use of tin solder.

According to another feature, the vertical central board (13) comprises temperature sensors and a thermostat.

According to another feature, the board (5) comprising the management system (BMS) is arranged vertically on the side of the battery pack so as to form a U with the other PCBs of said pack.

### BRIEF DESCRIPTION OF THE FIGURES

Other features, details and advantages of the invention will become apparent on reading the following description with reference to the appended figures, which illustrate:

FIG. 1 shows a functional diagram of the circuit of the battery according to a particular embodiment

FIG. 2 shows a simplified structural diagram of part of the battery circuit.

FIG. 3 shows a diagram of a part of the circuit showing the structure and operation of the discharge breaking device of the circuit breaker device and its actuation by the opening of a MOSFET, in a particular embodiment.

FIG. 4 shows a diagram of a part of the circuit showing the structure and operation of the load breaking device of the circuit breaker device and its actuation by an optocoupler, in a particular embodiment.

FIG. 5 shows a schematic view of the battery comprising several lines of accumulators, fixed by PCBs including the top PCB, the battery further comprising the fixed BMS.

FIG. 6 shows a sectional front view of the battery along the X-X′ axis passing through a line of accumulators.

FIG. 7 shows a schematic view in longitudinal section passing through the axis X-X′ passing through a line of accumulators.

FIG. 8 schematically shows the circuit of the top and bottom PCBs of the battery pack.

FIG. 9 shows the display of changes in the voltage at the terminals of the comparators U1 and U2 in the event of overcurrent according to one embodiment for a 24.4 Volt battery and a trigger voltage Td of 16 Volts

FIG. 10 shows the response of a digital integrator assembly operating according to the flowchart of FIG. 12 according to an embodiment used with a 16-volt battery and a trigger voltage Td of 12 Volts;

FIG. 11 shows the response of an analog integrator assembly according to another embodiment used with a 16-volt battery and a trigger voltage Td of 12 Volts; and

FIG. 12 a flowchart explaining the program for calculating the response of a digital integrator assembly according to an embodiment with paralleling of analog embodiments;

### DETAILED DESCRIPTION OF THE INVENTION

Many combinations can be envisaged without departing from the scope of the invention; the person skilled in the art will choose one or the other depending on the economic, ergonomic, dimensional or other constraints that he must respect.

In general, the present invention comprises a battery management system (BMS) for accumulators of a semi-modular element comprising a plurality of lithium cell elements connected in series to form a line, said battery management system for accumulators comprising at least two serial lines connected in parallel constituting the semi-modular element, and at least one detection circuit, characterized in that the detection circuit comprises at least one discharge or short-circuit detection device and at least one device for monitoring the voltage and temperature of a cell element, the detection circuit controlling a circuit breaker device comprising at least one switching device per line.

Advantageously, the battery comprises at least two lines of cell elements in parallel, each line having its switching device. The BMS is also configured to perform measurements on each line of cell elements forming lines of accumulators in order to be able to cut off a faulty block from the circuit independently of the others. This in particular allows the battery to remain functional, by delivering a lower maximum current but without the voltage of the series-parallel battery being changed. Thus, the breakdown is avoided despite the failure of one or part of the accumulators of the battery.

In certain embodiments, the detection circuit is connected on the one hand to the negative or positive pole of each set of cells or each battery and on the other hand to the positive, negative terminal, respectively, of the battery and uses at least two, of preferably only two, MOSFETs M1, M2 per line; a first MOSFET M1 performing a circuit break in the event of discharge below a threshold or during a short circuit, a second MOSFET M2 performing a load break in the event of voltage or temperature overshoot of an element of said circuit, the circuit further comprising electronic components (diode, resistors, capacitor), for example around the second MOSFET M2, performing load current limiting, each line comprising a load breaking device, when discharging, and current limiting when charging.

The presence and use of MOSFETs at each line of accumulators as charging and discharging breaking devices advantageously makes it possible to cut off the faulty line specifically from the circuit.

The protection against short circuits, overcurrents and deep discharge makes it possible to respect the values determined as thresholds. The system of the present invention activates the disconnection of the battery if the voltage and the duration reach said threshold values. The electronics thus also embed a device for limiting the load current, and for protection in the event of failure of the alternator of the device or of the charger.

It is well understood that the components allowing this limitation to the load are not on the discharge circuit, but on the load circuit/line.

In certain embodiments, the first MOSFET (M1) is connected by its source to the negative terminal of a set of cells, this first MOSFET (M1) receives, on its gate, a voltage source (V2) that drives (M1), this source delivering a chosen voltage (for example 6 to 10 V) so that the first MOSFET (M1) is on, a Zener diode (D3) is connected in opposition between the gate and the source of the first MOSFET (M1) and a capacitor (C2) protect the gate of the first MOSFET (M1) from excessively high or high-frequency voltages, and a Zener diode (D1) mounted in opposition between the gate of the first MOSFET (M1) and the drain and in series with a resistor (R3) and a diode (D2) in the forward direction in the drain-to-gate direction, (D1, D2, R3) limiting the switching speed of the first MOSFET (M1) and a circuit consisting of a Schottky diode (D4) limits the load current, this Schottky diode (D4) is mounted in opposition on the drain of the first MOSFET (M1) in the charging direction, and in series with a capacitor C1 and a resistor R1 connected to the positive terminal of the battery to also limit the overvoltage when opening the first MOSFET M1, in parallel on the Schottky diode (D4) a fixed resistor I1 is mounted that is connected on the one hand to the cathode of the diode and on the other hand to the drain of the second MOSFET (M2) whose source is connected to the anode of the Schottky diode (D4), the gate of the second MOSFET (M2) being controlled by an output of the detection circuit to prevent the load.

Advantageously, this assembly makes it possible to limit the switching speed of M1, to limit the overvoltage on opening of M1 and also to limit the current during charging.

In certain embodiments, the second MOSFET M2 is connected by its gate to the base of the phototransistor of an optocoupler whose emitter is connected to the source of M2; between these two points, a Zener diode D5 and a capacitor C5 are connected by the BMS card; the light-emitting diode of the optocoupler is connected by its cathode to the negative terminal of the battery or of the modular set of cells and receives, on its anode, the command sending a current into the LED in case of detected voltage or temperature overshoot of an element.

Advantageously, this arrangement allows the circuit or a line of the circuit to be cut off on the decision of the BMS, particularly in the event if the voltage or temperature of a detected element is exceeded.

In certain embodiments, the arrangement of the disconnection circuit associated with the two MOSFETs is interposed between the output pole of a line and the same terminal, of the same polarity (positive or negative), of the battery.

In certain embodiments, the BMS is connected to and controls each cell element and each accumulator line of the circuit and monitors the voltage of each cell and each serial line of cells.

This advantageously makes it possible to secure the battery at the single accumulator. Indeed, a battery could be faulty and unbalance the other batteries, leading to a security breach.

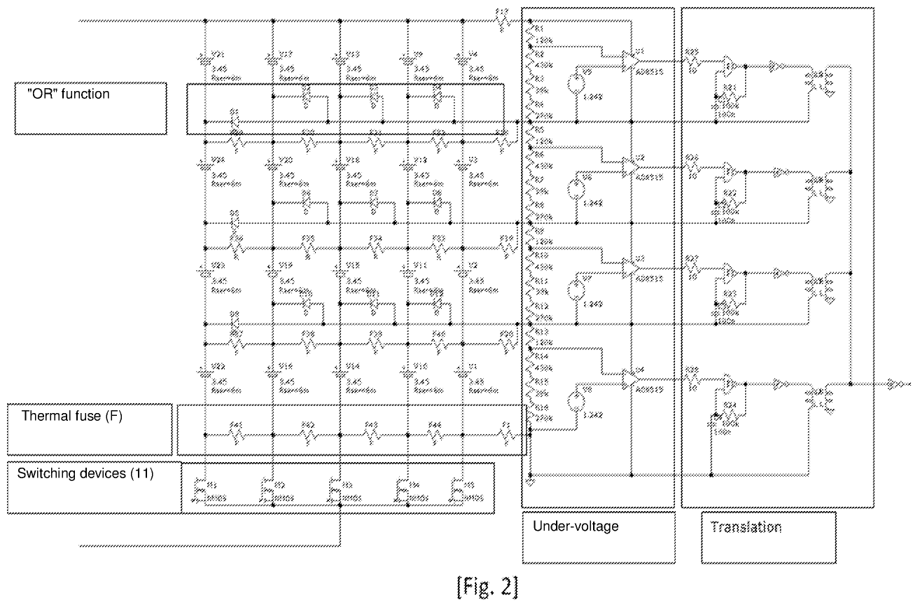

Preferably, the circuit does not comprise a shunt as shown in FIG. 2. The principle is to take a proportion of the voltage from each cell or from each parallel set of cells. In FIG. 2, each set of parallel cells (V4, V9, V13, V17, V21) is connected on the one hand each on one polarity to the cathode of a respective diode (D1, D2, D3, D4), each diode having its anode as common point to perform an OR function, and on the other hand by the other polarity with one end of a divider bridge (R1, R2, R3, R4) connected by its other end to the common point of the anodes for the first set of cells mounted in parallel as shown at the top of FIG. 2 in the square (undervoltage). The voltage proportional to the OR of the voltages of each cell is used, either analogically by a comparator supplied on its other terminal by a reference voltage, or digitally as explained below.

The principle of measurement via an integrator assembly as described in the present application is a principle of measurement of an overall voltage that makes it possible to trace back to a current value. This principle is only valid in the battery field when the internal resistance of the voltage generator is known. In this case and only in this case, said integrator assembly can be used either analog (as shown in FIG. 2) or digital.

For example and non-limitingly, the response or output of a digital integrator can be calculated as follows:

Consider a voltage variation represented by x=(−0.25*V_{global}+2.5)*weighting, where V_{global} is a voltage obtained from the battery voltage by the use of a voltage divider bridge (R1-R2 or R9-R4) and weighting is a variable that allows the integration constant to be changed. The above equation can be modified according to the accumulators used.

The output or response, y, of the digital integrator having the general form y=Integration(x), where Integration( ) represents the integral calculus, can be calculated using either as a first progressiveness equation consisting in taking the value of x, defined above, and raising it to an even power (2, 4, 6, 8, etc.), for example y=x². A second progressiveness equation is given by y=Rate*(−ln(x)), with Rate, the integration constant expressed in seconds.

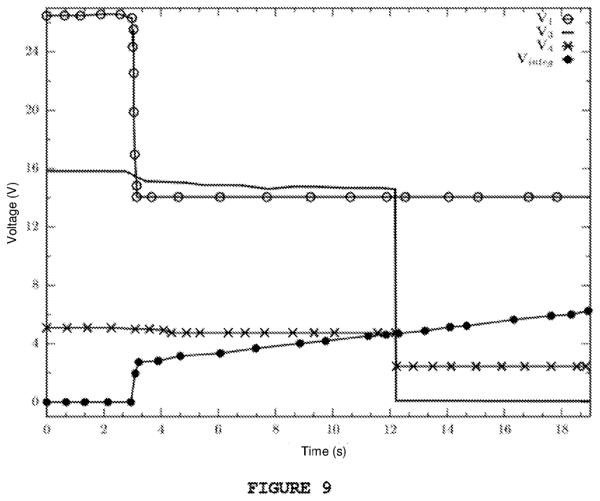

To get even closer to the analog integrator (FIG. 9, 11), a second progressiveness equation defined, for example and in non-limitingly, by y=Rate*(−ln(x)), with Rate, an integration constant expressed in seconds, can be used. This equation makes it possible to imitate the behavior of a capacitor whose voltage across its terminals evolves like an exponential.

FIG. 12 shows a diagram for calculating the response of a digital integrator according to the second progressiveness equation. Each calculation step represents the components of the detection device that can be involved in the calculation operations. The diagram can be divided into three phases: a measurement (PM) and comparison phase, an integration phase (PI) and a disconnection phase (PD).

In the measurement phase (PM), the voltage divider bridge R1-R2 (or R9-R4) makes it possible to determine a measurement V=V_{global} of the voltage at the input of the detection device from the voltage V1 of the battery.

The “Refintegration” variable is the integration reference and corresponds to a voltage value below which the input signal V will be integrated. If the voltage V is greater than the “Refintegration” variable, the battery is in a situation of normal operation. If V is less than the “Refintegration” variable, the battery is operating abnormally and the process that can lead to the disconnection of said battery is triggered. This variable Refintegration is therefore equivalent to the reference voltage V2 One then enters the integration phase, where the response of the integrator must be calculated.

If the voltage V is lower than the “Refintegration” variable, the program triggers either the use of a normal integration constant in the calculation performed, or the use of weighting for the integration constant. This weighting as represented in the PI box is used if the voltage is lower than a second comparison variable called “RapidThreshold,” which makes it possible to define a voltage threshold from which the “weighting” variable (defined above) is used in the calculation of the voltage variation or not. For example and non-limitingly, the voltage variation has a general form of type x=(slope*V_{global}+ordinate)*weighting.

If the difference or variation of the input voltage V, dV, between a time t1 and a time t2 (or between two successive measurements of the voltage V), defined by dV=|V(t2)−V(t1)|, is greater than the “RapidThreshold” variable, the “weighting” variable takes the value 5, for example. If, on the contrary, said difference or variation of the voltage V, dV, is less than the “RapidThreshold” variable, the “weighting” variable takes the value 1. Which corresponds to using a normal integration constant.

The voltage measurement time pitch can be comprised, for example and non-limitingly, between 1 ms to 100 ms. The value of the “RapidThreshold” variable can be defined according to the measurement time pitch and by monitoring the voltage variation between two times t1 and t2, corresponding to said time pitch, used to perform the voltage measurements, in order to improve the conditions for detecting abnormal conditions. For example, and non-limitingly, for FIG. 4B, the measurement time pitch used is 10 ms and the “RapidThreshold” value is 0.01 Volt. This corresponds to a voltage drop dV=0.01 Volt every 10 ms.

The “Ordinate” and “Slope” variables obtained by storing the measurement points and calculating, for example by fitting the stored voltage data or by using two points of the stored voltage curve between two times t1 and t2 to deduce the “slope” (for a linear voltage variation) then the “ordinate,” make it possible to define the voltage variation. In the example where x=(−0.25*Vglobal+2.5)*weighting, the slope is −0.25 and the ordinate is 2.5.

The step of comparing the voltage variation dV is equivalent to a step of comparing the calculated slope with the stored “Rapidthreshold” value, i.e., if the slope exceeds the “Rapidthreshold” value, applying a weight coefficient (for example, 5) increasing the acceleration of the evolution of the integral so that it crosses the trigger voltage threshold Td more quickly, or if it is not exceeded, a weight coefficient without acceleration effect (for example, 1).

Once the voltage variation is obtained, the signal is integrated according to the second progressiveness equation, for example. The output signal thus corresponds to the integration of the input signal.

The “Progressiveness coeff” variable corresponds to an integration constant (Rate in the second progressiveness equation).

In the embodiment by digital integrator, those skilled in the art will understand that the assembly using the comparators U1 and U2 is replaced by a microprocessor playing the role of a digital comparator (Un). Said microprocessor is equipped with a storage memory allowing the storage of the “Refintegration” and “RapidThreshold” threshold variables and the “Ordinate” and “Slope” calculation variables defined according to these thresholds. The memory also contains the calculation program allowing the collection of the voltage curve points (V_{global}, etc.), the comparisons and decisions, the implementation of the equations, the integration and the decisions represented in the flowchart of FIG. 12.

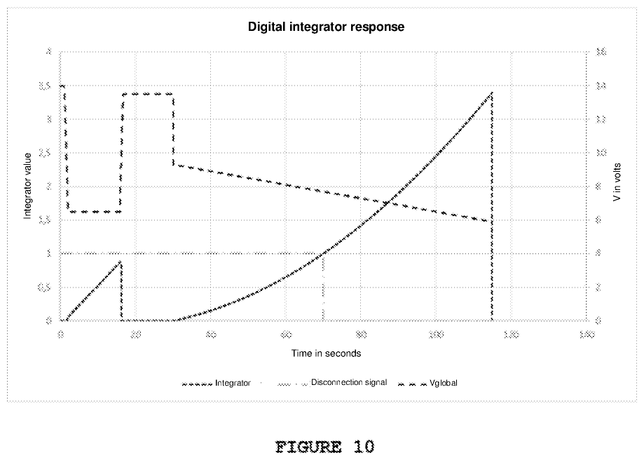

As input, the digital circuit only receives the voltage V_{global} from the common point of a divider bridge between a resistor R1 and a resistor R2 and performs measurements according to a determined frequency to observe the voltage V_{global} curve, then from the detection of the crossing of the “Refintegration” threshold, which, in the example of FIG. 10, is chosen to be less than 3 volts per cell element or 12 volts for a battery of 4 cell elements in series from this reference voltage V2, the microprocessor program triggers the calculations to obtain the comparison with the “Rapidthreshold” variable of the variation dV of the voltage V_{global} between two successive instants t1 and t2 (or between two successive measurements) in order to determine the use or not of a “Weighting” variable. Thus, in the case of a start causing a significant drop in the voltage from 14 to almost 6 Volts, the “rapidthreshold” value for example and non-limitingly being fixed at 0.01 Volt in the example of the FIG. 10, the rapid threshold will be crossed and the integration will be done with weighting to avoid an excessively fast cut-off preventing starting. In the diagram shown in FIG. 10, it is observed that the battery voltage having dropped rapidly to almost 6 Volts and remaining constant for about 18 seconds, the digital circuit integrates the constant value in a straight line, which remains below the detection or trigger voltage Td, which is chosen at 1 Volt. The response of the integrator or output voltage can, for example and non-limitingly, be obtained with a program such as the one defined in the appendix to this application where the “GeneralVoltage” variable corresponds to the voltage V_{global} at an instant t1=t, and the “LastGeneralVoltage” variable represents the value of the voltage V_{global} at instant t2=t−1. The “ORDINATE_ORIGIN” variable corresponds to the “Ordinate” variable defined above and the “lastIntegratedValue” variable corresponds to the integral calculation or the integrator's response.

The calculation of the integral or of the integrator's response can comprise taking into account the “Slope and/or Ordinate” variables calculated by the microprocessor from the data of the recorded voltage curve V_{global}.

Integration is triggered as soon as the overall voltage V_{global} drops below V₂=Ref integration=9 Volts.

Then, during its use, the voltage of the battery drops suddenly from 14 Volts to about 9 Volts, then decreases slowly over time along a straight line down to 6 Volts. The ordinate of the line is approximately 2.3 Volts and the slope is lower than previously, and the variation dV of the voltage between two successive measurements may be greater (depending on the value of the slope) than the “rapidthreshold” variable (for example, 0.01 Volt in the example shown in FIG. 10).

When the value at the output of the integration reaches the threshold corresponding to the detection or trigger voltage Td of 1 volt, the cut-off is triggered.

Finally, in the digital version or variant, during a short circuit, the voltage V_{global} drops very quickly to a very low value, a short circuit detection threshold is stored, and as soon as the processor detects the crossing of this threshold, it activates the disconnection signal.

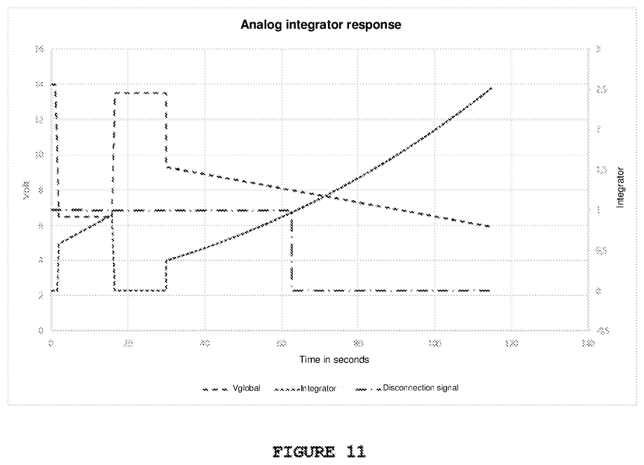

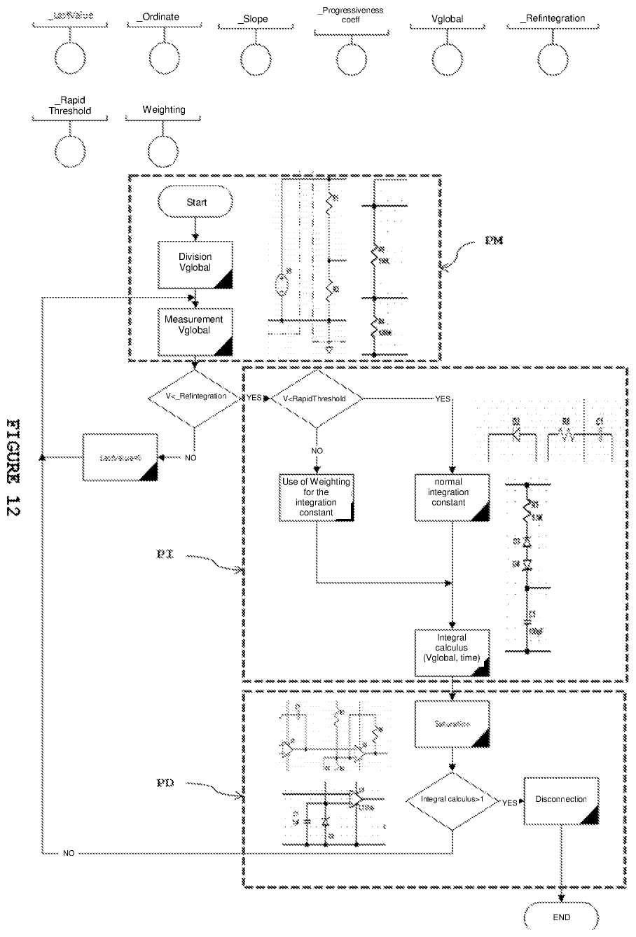

In FIG. 10 illustrating the response or output signal of a digital integrator according to the example described above, the digital integrator exhibits behavior similar to that of an analog integrator (FIG. 11) in the time interval comprised between t=40 s and approximately t=120 s.

In the disconnection phase, the calculation of the response is used to check whether a disconnection should be triggered (or activated) or not. Disconnection is activated when the response of the integrator is greater than a given threshold corresponding to the detection or trigger voltage Td. In the example above, illustrated by FIG. 10, 11, 12, this threshold is set at approximately 1 or 1.24 Volts. For example and non-limitingly, the threshold value can be normalized to 1.

Below, a non-limiting example is presented of a digital integrator program to implement the response of the integrator in FIG. 10:

```
floatlastIntegratedValue = 0;
constfloat_SLOPE = −0.25;
constfloat_ORDINATE_ORIGIN = 2.5;
constfloat_COEF_PROGRESSIVENESS = 1;
constfloat_VALUE_REF_INTEGRATION = 10;
constfloat_RAPID_THRESHOLD=0.01;
constfloat_WEIGHTING=1;
loop( ){
  floatGeneralvoltage = IO_Voltage(1) * 7;// recovery of the battery
  voltage that
has been divided and rescaled
  lastIntegratedValue = Integration(generalvoltage, lastIntegratedValue);
  if (lastIntegratedValue>= 1 ) Disconnection ( );
}
floatIntegration (floatGeneralvoltage, floatlastValue){
  if(generalvoltage<= _VALUE_REF_INTEGRATION){
    if ((LastGeneralVoltage −
    generalVoltage)>_RAPID_THRESHOLD ||
  (LastGeneralVoltage − generalVoltage)<
  −_RAPID_THRESHOLD)
    _WEIGHT = 5;
    else
    _WEIGHT = 1;
  float x = (_SLOPE * generalvoltage +
  _ORDINATE_ORIGIN)*_WEIGHT;
  float y = integration(x, _COEF_PROGRESSIVENESS);
int value = lastValue + y;
return value;
  }
  return 0;
}
```

Thus, the BMS comprises at least one deep discharge, overcurrent and short circuit detection device (2) in each unitary element or modular assembly of the battery and comprises at least one BMS device, the BMS being characterized in that the detection device is unique and comprises a comparator U1 that directly compares a proportional voltage, in a determined ratio, with that of the unitary element or of the modular assembly, without using a resistive shunt, in order to compare it with a reference voltage V2 to activate or not activate the disconnection of the battery (4) according to the variations of the voltage of the unitary element or of the modular assembly; the proportion ratio between the measured voltage and the reference voltage corresponds to the ratio between the reference voltage V2 and the trigger voltage Td from which the circuit breaker device is actuated.

In a variant of the BMS, a microprocessor equipped with at least one storage memory allowing the storage of at least one “Refintegration” threshold variable and of a stored detection voltage value Td; the memory also containing the program executed by the microprocessor allowing the collection of the points of the voltage curve Vglobal, the comparisons of the voltages Vglobal with “refintegration” and of the calculated voltage integral (Vinteg) with Td and decisions, the implementation equations allowing the integration, the microprocessor receiving as input the voltage Vglobal coming from the common point of a resistor divider bridge connected between the two poles of the cell or of the set of cells and storing the measurements according to a determined frequency to observe the voltage curve Vglobal, and compare the values of the voltage curve Vglobal to the “Refintegration” value, then when crossing of the “Refintegration” threshold is detected, said threshold being defined by the value stored in the memory, triggering the integration calculations of the curve Vglobal and comparing the values of the calculated integration curve (Vinteg) with a stored detection voltage value Td to activate the circuit breaker device performing the cut-off.

According to a variant, the memory also comprises the value of a “Rapidthreshold” variable stored in order to determine, by comparing the instantaneous voltage Vglobal with the “Rapidthreshold,” whether the calculation of the integral of the voltage curve Vglobal must take a weighting coefficient into account.

According to another variant, the calculation of the integral can take into account the “Slope and/or Ordinate” variables, calculated by the microprocessor from the data of the recorded voltage curve Vglobal.

In certain embodiments, the detection circuit comprises one or more of the following functionalities:
Cell voltage balancing;
Detection of excessively low voltage and open circuit
Detection, by a voltage measurement circuit, of short-circuit, deep discharge and overcurrent to trigger the disconnection of a group of cells by opening the circuit
Detection of excessively high voltage of one of the battery cells and opening of the circuit

In certain embodiments, the voltage balancing is performed by a diode “OR” function connecting each of the cells connected in parallel with the negative polarity of the divider bridge of the short-circuit, deep discharge and overcurrent voltage measurement circuit.

In certain embodiments, each cell element of a line is connected to each adjacent cell element of another line by an element constituting a thermal fuse, preferably resettable.

In certain embodiments, the detection circuit comprises the following functionalities: integrates temperature monitoring that remains constantly active, even if the battery is “off,” by analyzing the temperature in the battery envelope, measured by a probe mounted on the central part 13 of the cards of each module.

In certain embodiments, the electronic components of the circuit breaker device limiting the current to the load, preferably only to the load, for regulating the load current comprise a component such as a resistor, which is conductive in one direction, and resistive, like a diode connected in opposition, in the other direction.

In certain embodiments, the circuit is arranged in such a way that the charging and discharging switching devices are controlled independently.

The invention also relates to a high-current, semi-modular, series and parallel battery pack consisting of lithium accumulator cells of the same characteristics connected in series to form a line by connections in a given direction S corresponding to the direction of the high currents to obtain the necessary voltage, and intended to be able to be associated in parallel with another line of accumulator cells, said pack using a management system as described in this description, and characterized in that:
a pair of upper 71 and lower 72 bezels that delimit a set of cylindrical housings with a square or polygonal or circular section defining, in the same direction S, at least one line of cylindrical housings with a square or polygonal section each holding a lithium accumulator cell;
the connections between the accumulator cells of the same line in the direction S are ensured by wide tongues (9) connecting, on each upper or lower face of the module, each pair of adjacent cells connected in series by their poles of opposite polarity in the first direction S, the connecting tongues on one face being offset by one cell on the other face;
the bezels comprise at least two lines of housings parallel to the direction S in which at least two lines of cells are arranged in a direction perpendicular to S and interconnected either by thin tongues acting as a fuse or by resettable fuses (F, FIG. 2), in the direction P perpendicular to the direction S, each fuse connecting two cells belonging to two different parallel lines to make a parallel connection between each cell of two parallel sets of serial cells.

In certain embodiments, the circuit is arranged in such a way that the charging and discharging switching devices are controlled independently.

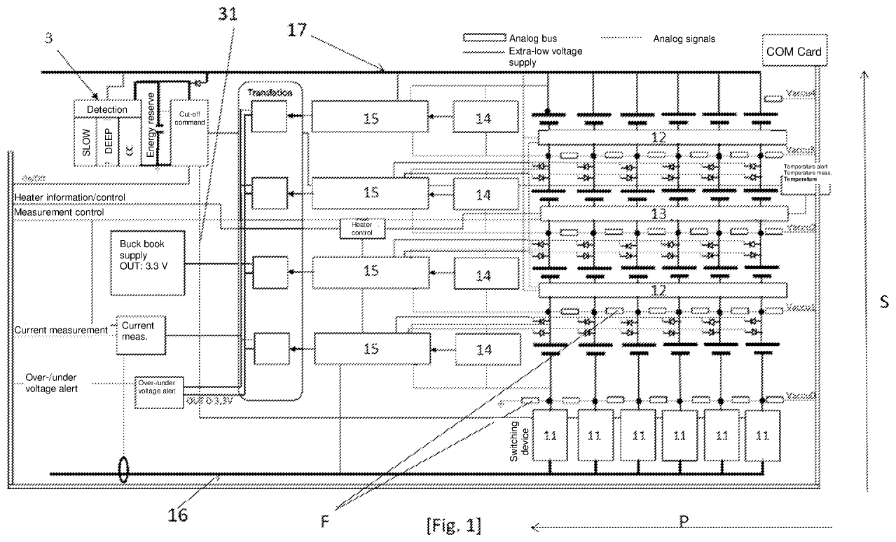

In certain embodiments, the bezels hold PCBs (printed circuit boards) by the sides at the upper 71 and lower 72 part, which PCBs comprise the electronics and the electrical connections between the electronic components of the management system and the cells of the semi-modular block;
intermediate PCBs (12, 13, FIG. 1) are arranged vertically between the cells in a direction perpendicular to the direction S comprise at least the heating resistors of the semi-modular assembly and these resistors are connected on demand from the management circuit to a power supply;
the PCB part arranged under the cells contributes to recovering the potentials of each of the cells of the modular block to supply them to the voltage management and balancing circuit of the modular block management system.

It is understood that “cell element,” “cell” or “accumulator” means any individual system configured to store electrical energy in a different form, here preferably by electrochemistry using Lithium-ion technology.

In certain embodiments, resistors are mounted between two contact pads (not shown) on the upper and/or lower PCBs and the contact with the cells and the tracks of the upper or lower printed circuit boards are made by elastic pins (Pogo or conical coil springs, for example) arranged between the cells and the conductive face comprising the contact pads of the printed circuit board, thus avoiding the use of tin solder.

Advantageously, the present invention makes it possible to increase the current by adding batteries in parallel rather than in series without balancing problems, and without the need to resize the constituent elements of the circuit (increase the capacity of the accumulators and the sizes transistors (switching devices). The transistor switching device, within the framework of this solution, is adapted to the current of the line, which allows easy balancing. Indeed, in some solutions, such as TrueBlue Power, blocks of cell elements in parallel are arranged in series one after the other with a single switching device composed of a certain number of MOSFETs arranged in parallel with each other, so that the current is not balanced. In fact, balancing diode or switching device currents in parallel is almost impossible, because the forward voltage decreases sharply with temperature. Thus, the hottest element carries all the current, which further increases its temperature until it is destroyed. Thus, if one of the switching devices heats up more, it will receive more current and heat up more by avalanche effect, which is to be avoided at all costs. Conversely, the present invention makes it possible to increase the current and the capacity without theoretical limit, because the distribution of the current is the same in all the switching devices, which therefore do not need to be oversized.

In other words, in duplicating the elements in parallel, it is important to guarantee the proper functioning of the assembly, and in particular the monitoring of all the cells. The more the number of blocks in parallel is increased, the more the number of connections between the cells and the boards is increased. The use of “pogo pins” (elastic pins) or conical coil springs limits the number of welds while guaranteeing easy assembly by the bezels that hold the cells and the PCB boards, on which one end of each elastic pin is secured mechanically to the PCB and electrically to the bonding conductor. The other end of the pin comes into contact with a pole of the cell corresponding to the location of the pogo.

In addition, the present invention proposes one switching device per line of cell elements in order to be able to only partially cut the circuit and thus allow, at least momentarily, safe use of the battery despite the occurrence of a problem (short circuit, overload or deep discharge). Maintenance of the voltage is then observed with a lower available current.

Preferably, a single switching device is present per line of accumulators in series. In certain embodiments, the overall voltage per line of cells and the voltage of each cell is monitored by the BMS.

In certain embodiments, the vertical central board (13) comprises temperature sensors and a thermostat.

Thus, in certain embodiments, the board (5) comprising the management system (BMS) is arranged vertically on the side of the battery pack so as to form a U with the other PCBs of said pack.

In certain embodiments, the vertical central board comprises temperature sensors and a thermostat.

Advantageously, the use of an optocoupler allows, among other things, communication between different PCBs.

An example of a method for forming a battery pack according to certain embodiments as described above comprises the following steps:
pre-welding blocks (2) (4 by 1 or 8 by 1) of accumulators (20) in series by the tongues (9),
placing blocks on the lower bezel (72) and on the lower PCB (6),
Placing the upper bezel (71) and the upper PCB (4, 4′),
Riveting the accumulators on the power bar of the upper PCB (4) [and riveting the upper PCB (4) to the upper bezel (71), which allows easier, faster assembly with additional reliability and safety.

“The contact between the cells (20) and the conductive tracks connecting the cells to the components are made by the elastic pins (10) or conical coil springs.

In certain embodiments, as for example illustrated non-limitingly in FIG. 1 in a functional manner, a BMS (Battery Management System) is configured to measure the voltage and the current across the terminals of the various cell elements and the overall voltage of each line, and to measure the temperature at these cell elements and/or lines. Depending on the measured temperature, the BMS (3) can send a signal to configured heaters to heat the cell elements in order to keep them at the optimum operating temperature. When the BMS measures a voltage or a current exceeding predetermined threshold values, corresponding for example to a slow or deep discharge, an overload or a short circuit, it is configured to send a cut-off command to the switching device associated with the line of accumulators comprising the faulty cell element. This makes it possible to cut a line without cutting the entire circuit. This makes it possible in particular to continue to operate the battery, in a “degraded” mode making it possible to continue to operate, at least for a certain time, the element using the battery, for example an aircraft, without damaging the battery, until the battery can be safely disabled and repaired.

Advantageously, such a configuration allows the design of a simplified circuit, with a single − terminal and a single + terminal, rather than two + terminals, depending on the use of the battery (charging or discharging) as is the case in some prior arts.

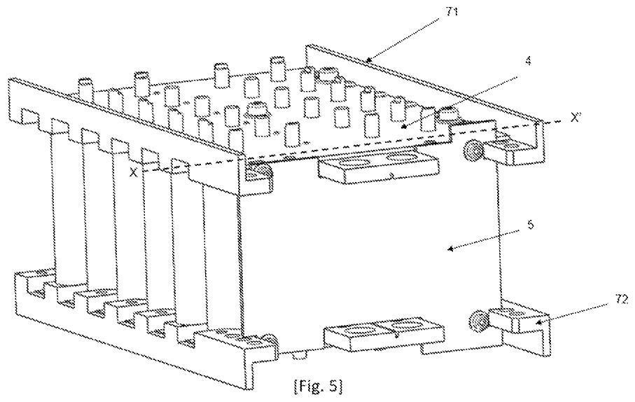

More particularly, FIG. 2 illustrates an embodiment by way of non-limiting example of the present invention, in which resettable fuses are embedded between the different inter-battery potentials. This circuit is preferably placed on the upper PCB (see FIGS. 5 to 7). This makes it possible to isolate a defective (short-circuited) accumulator, because otherwise this accumulator would cause high currents and could lead to the destruction of the battery. With diodes, the “or” functions of all the accumulator lines are realized by potential, so for a battery for example of 12 V, one obtains 4 potentials for the low voltage and 4 potentials for the high voltage. This voltage is then compared to a predetermined threshold and a cut-off is performed if these thresholds are exceeded. There is an undervoltage circuit and an overvoltage circuit whose detections are based by measurement at the terminals of each accumulator and are concatenated using diodes.

The supply voltages of the under/over-voltage and balancing blocks are carried out directly at the terminals of the accumulator; a circuit is obtained that is supplied between 0-4 V (0-4 V, 4 V-8 V, 8 V-12 V, 12 V-16 V), which poses a problem for retrieving the output information. An adaptation stage is therefore required in order to achieve a level translation. The output of the comparators is coupled with a pulse transformer by oscillating a hysteresis logic gate.

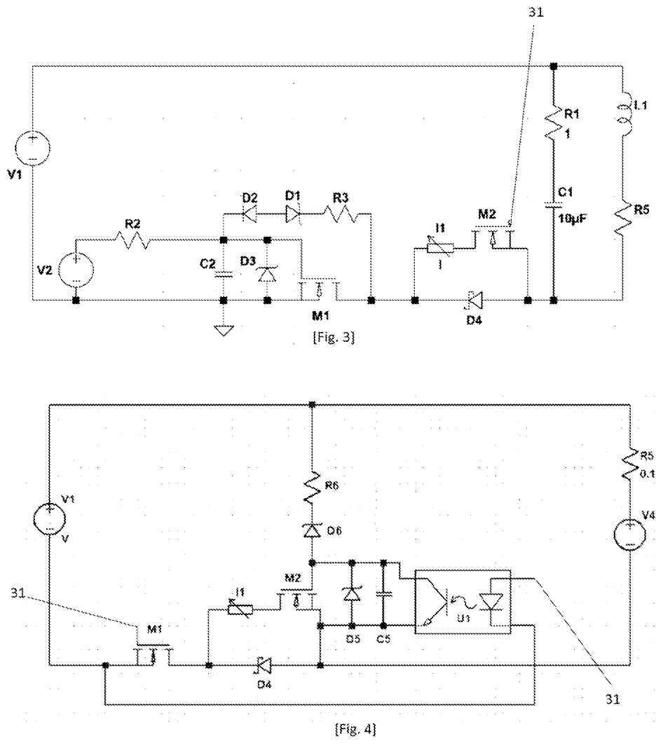

FIGS. 3 and 4 shows the circuit of the switching device in a simplified way: certain elements are not shown (the components linked to M2 in FIG. 3 and the components linked to M1 in FIG. 4, respectively) in order to simplify the reading of said figures.

MOSFET transistors are used for the switching devices. This advantageously makes it possible to obtain switching devices having very low static consumption both in the on state and in the off state. FIG. 3 non-limitingly details an example of MOSFET-based discharge cut-off. V1 is the battery and L1-R5 is the load (e.g. starter). The diode D4 is conductive during discharging. It must withstand the short-circuit current for at least 10 ms, and dissipate the Joule losses during a high-current discharge. The short-circuit current is estimated at 264 A for an 8S1P assembly of A123 Systems elements. Cut-off during a short circuit or at the end of discharge is ensured by the MOSFET M1, which must also withstand the short-circuit current for at least 10 ms. V2 is the voltage source that drives M1 (coming from the detection circuit). Ideally, this source delivers 6 to 10 V so that M1 is on. The Zener diode D3 and the capacitor C2 protect the MOSFET gate from too high or high-frequency voltages.

When opening M1, an overvoltage may occur greater than the Vds of M1 due to the cancellation of the current in the inductor L1. D1 is a Zener diode that, together with the resistor R3 and the diode D2, limits the switching speed of MOSFET M1.

The R1-C1 assembly (resistor-capacitor) is found at the + and − terminals of the battery and also makes it possible to limit the overvoltage when M1 opens.

By way of example and non-limitingly, FIG. 4 non-limitingly presents an example of a circuit comprised in an embodiment of the invention allowing the limitation of the load current, as well as the cut-off of the load. V4-R5 is the device alternator or a charger. It provides 28 V in normal operation, but can output a higher voltage in the event of a fault in its regulator. Standardized tests give a voltage of 1.5 times the nominal voltage of the battery, i.e. 42 V. In practice, it is possible for this voltage to reach 80 V. The limitation of the load current is provided by a diode D4 conducting in the discharge direction, and blocked in the charging direction, in parallel with a current limiting resistor I1.

Thus, the diode D4 must withstand the short-circuit current. This is feasible for a modular battery, but very difficult for a high-capacity battery. Indeed, a 17 Ah non-modular battery, for example, can supply a short-circuit current of more than 2000 A. Thus, the diode should be able to carry this current. Diodes that can carry this current do not exist as an “electronic component,” and in practice several lower-current components can be connected in parallel. However, balancing diode currents in parallel is almost impossible, because the forward voltage decreases sharply with temperature. Thus, the hottest diode carries all the current, which further increases its temperature until it is destroyed.

The MOSFET M1 is configured at its gate to be always on in the charging phase. The diode D4 is blocked on recharging, and the load current passes through I1 and M2. I1 is a load current limiting power resistor. In other equivalent embodiments, I1 can also be a combination of resistors and polyswitches, or a semiconductor current regulator. The MOSFET M2 is on when its gate-source voltage V_{gs} is at 10 V, for example. D6 is an 18 V Zener diode, for example, and D5 is a 10 V Zener diode. Thus, under a voltage of 28 V (alternator voltage), D6 and D5 are at the limit of conduction, there is no current in R6 and V_{gs}=10 V and the load current passes through I1 and M2. The voltage values of the diodes D5 and D6 therefore make it possible to define the value of the gate-source voltage of MOSFET M2. The capacitor C5 protects the gate of MOSFET M2 from high-frequency voltages.

Detecting a fault in the charger comprises two measurements: the measurement of the voltage of each element, and the measurement of the overall voltage. If the voltage of an element exceeds 4 V, for example, or if the overall voltage exceeds 32 V, for example, then the load breaking device is actuated. Charging is again possible when the voltage has dropped below 26 V, for example, owing to a hysteresis comparator.

In the digital variant, the microprocessor will be wired with the battery to receive, on its inputs, both a voltage representative of the voltage of each cell element V_{cec} constituting the battery and also the overall voltage measurement V_{global} of the battery, available on the conductors leading to the outer battery terminals. The program executable by the microprocessor will comprise a code module monitoring these two voltages V_{cec} and V_{global}; after comparing each one with a respective determined stored threshold, it triggers the cut-off by activating the disconnection element (31) when this threshold is exceeded.

Regarding the triggering of the load breaking device, if the voltage or temperature of a single element is exceeded, M2 is blocked by the optocoupler U1. Indeed, the optocoupler U1 comprises an LED (Light-Emitting Diode) and a transistor. Thus, if the voltage or temperature of a single element is exceeded, a current flows through the LED and causes the transistor to conduct. The gate-source voltage V_{gs} of the MOSFET M2 is returned close to 0 V (Vcesat for saturation collector-emitter voltage of U1). M2 then cuts the load current (D4 and M2 are blocked). The current in the LED of U1 is taken from the common point between M1 and the battery, therefore from the voltage of the battery, due to the disconnection between the 0 V of the battery and the 0 V of the alternator or charger.

Regarding the triggering of the load breaking device, if the voltage or temperature of an element is exceeded, M2 is blocked by the optocoupler U1: a current in its LED causes the transistor to conduct, thus the Vgs of the MOSFET is returned close to 0 V (Vce sat of U1). M2 then cuts the load current (D4 and M2 are blocked). The current in the LED of U1 is taken from the voltage of the battery due to the disconnection between the 0 V of the battery and the 0 V of the alternator.

The solutions proposed until now describe external modular architectures where several batteries are coupled to an external data bus allowing information to be escalated to a supervisor.

The architecture proposed by the invention is on the contrary internal to the battery, and can be a modular architecture as shown by way of non-limiting example in FIG. 5. This figure thus shows a schematic view of the battery comprising several lines of accumulators, fixed by PCBs to form a “U.” More precisely, a battery pack according to certain embodiments as illustrated comprises a plurality of blocks of cell elements in series (preferably 4 by 1 or 8 by 1), the blocks being framed at their two longitudinal ends by upper and lower bezels. At their upper end, the accumulator blocks are coupled to a PCB, called “upper PCB,” for example at orifices in the PCB configured specifically to receive said end of the blocks. Rivets secure the upper PCB to the upper bezels. This assembly forms the upper face of the battery pack. The same couplings and fastenings are done with a lower PCB on the opposite face of the battery pack, called the lower face. Fixed on a third face of the battery pack is a third printed circuit board (middle PCB), also fixed to the upper and lower bezels, so as to form a “U” with the upper and lower PCBs.

In addition, although not shown in FIGS. 5 to 7, intermediate PCBs are arranged vertically between the cells in a direction perpendicular to the direction S and comprise the heating resistors (heaters) of the semi-modular assembly, and these resistors are connected on demand by the management circuit to a power supply to cause said heating.

In certain embodiments, a pair of upper 71 and lower 81 bezels delimits a set of cylindrical housings of square or polygonal or circular section defining, in the same direction S, at least one line of cylindrical housings with square or polygonal section each holding a lithium accumulator cell.

In certain embodiments, the PCB boards held in the upper and lower bezels comprise the electronics and the electrical connections between the electronic components of the management system and the cells of the semi-modular block.

The bezels comprise at least two lines of housings parallel to the direction S in which at least two lines of cells are arranged in a direction perpendicular to S and interconnected by thin tongues, in the direction P perpendicular to the direction S, each thin tongue connecting two wide tongues of cells belonging to two different parallel lines to achieve a parallel connection of two parallel sets of serial cells. The wide tongues are preferably made by elastic pins (Pogo pin or conical coil springs, for example) arranged between the wide tongues placed on the cells and the conductive face comprising the contact pads of the printed circuit board, thus avoiding the use of tin solder.

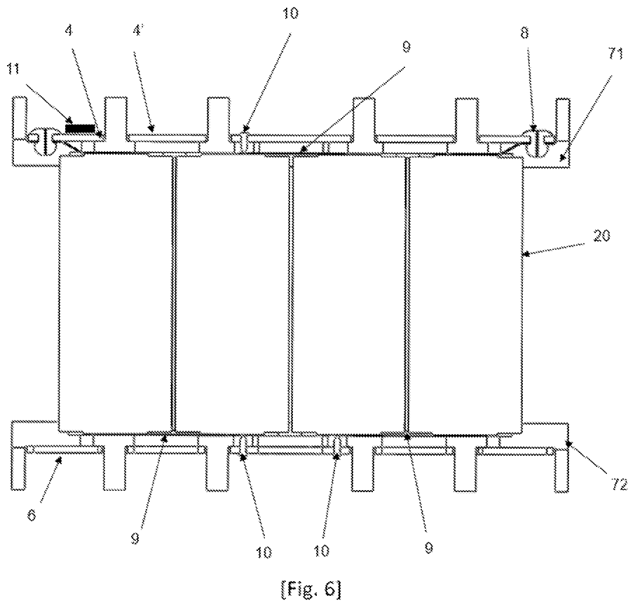

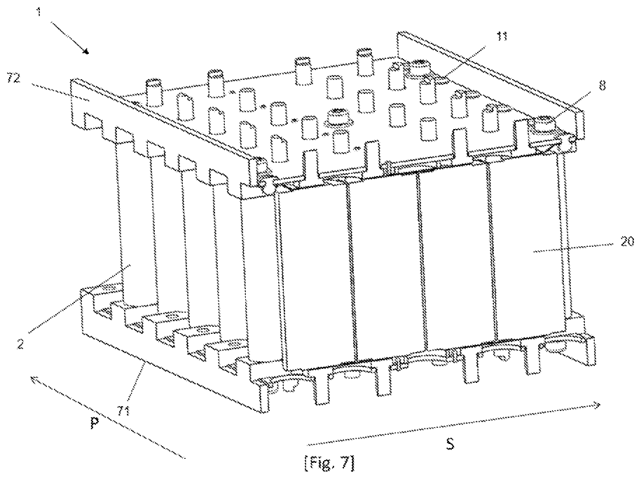

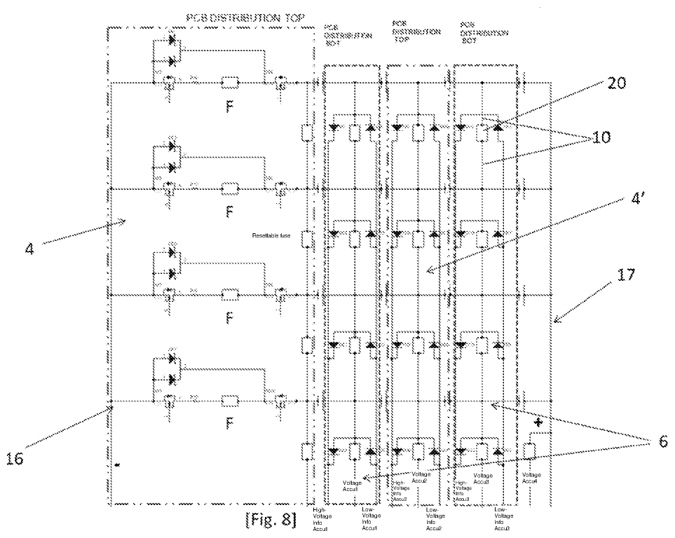

By way of example and non-limitingly, FIG. 6 shows a front sectional view of the battery along the axis X-X′ passing through a line of accumulators, while FIG. 7 shows a schematic view in longitudinal section passing through said axis X-X′ [passing through a line of accumulators?]. A switching device (11) is coupled to each line of cell elements in series, as shown in FIG. 7. The ends of the cell elements (20) are thus inserted into the housings of the upper and lower bezels (71, 72). Thin tongues (9) make it possible to interconnect two lines of cell elements (20).

By way of example and non-limitingly, FIG. 8 schematically shows the circuit of the upper (4, 4′) and lower (6) PCBs of the battery pack. The PCB part 4 is connected on the one hand to each parallel cell of each end of the serial line (here four serial lines) and on the other hand by the power conductor (16) (high current) to the output terminal of the battery. This board 4 comprises the switching devices referenced by their MOSFETs M3 to M10, which correspond in pairs M3, M4; M5, M6; M7, M8; M9, M10; to each of the switching devices 11 shown schematically in FIG. 1. It should be understood that each element M3, M4 of a pair represents, respectively, in a simplified way, the electronic diagram of FIG. 3 for each reference M3, M5, M7, M9 of FIG. 8 and the electronic diagram of FIG. 4 for each reference M4, M6, M8, M10 in FIG. 8.

Additionally, the battery pack and the system may comprise various features to improve their usability and reliability.

Thus, the present invention may comprise a communication board making it possible to recover the various properties of the analog sensors, to log them, to calculate certain parameters of the state of health, load (SOH and SOC) type. It preferably embeds a CAN link (standard protocol in the automobile and aeronautics industries), a LIN link, and possibly an LCD screen for the HMI (Human-Machine Interface).

The battery has a power off/on function. This function makes it possible to store the battery, to carry out maintenance operations with increased safety. The user can also switch off the battery when he is not using it to avoid any untimely discharge of the battery and any risk of fire linked to a malfunctioning instrument.

Heaters are preferably made by wrapping copper on an inner layer of a PCB. This allows a simple and inexpensive means of production. This technique makes it possible to integrate connectors.

Preferably, the block does not include tin solder during assembly. This makes it possible to propose a system that does not include all the wires of certain devices of the prior art. Connectors are thus placed on the heaters, on the bezels and on the upper and lower distribution PCBs.

The BMS is then connected to all these connectors by a mechanical fastener so as not to risk disconnecting a connector during vibrations when in use.

Unlike some prior art batteries, the system of the present invention has only one active mode of operation for all the safety features provided by the BMS, and has no standby mode. This is made possible by the use of very low-power consumption components. Indeed, owing to the low standby current of approximately 80 μAmpere, for example, the safety functions of the BMS of the battery can remain permanently powered up without the maximum storage duration being penalized.

The battery pack of the present invention exhibits very good resistance to impacts and vibrations. Indeed, it is mechanically separated into two parts: an external part secured to the case, an internal part including the accumulator cells. The two parts are preferably mechanically decoupled by a flexible material that improves the resistance of the battery to impacts and vibrations. The front panel, the user interfaces and the BMS electronic board are secured to the case. The accumulator cells, the spacers, the heaters, the electromechanical relay and the “distribution board” form the mechanically decoupled internal part. All the electrical connections between the internal part and the external part have a certain flexibility in the three directions of space (axes x, y, z).

Good thermal insulation allows better efficiency of the electric heater: lower electricity consumption to bring the elements to their ideal operating temperature. The thermal insulation also makes it possible to reduce the temperature variations undergone by the accumulator cells in the case of an aircraft, which would alternate periods on the ground at high temperature (for example: +30° C.) and periods in flight at very low temperature (for example: −10° C.). This may be the case for devices for dropping parachutists. The battery of the present invention may, for example, use aircraft-grade flame retardant cork. The advantage of this material is that it simultaneously performs the function of thermal insulation, thermal protection and mechanical decoupling. Thermal protection and thermal insulation also act as electrical insulation between the live parts inside the battery and the metal case. Because there are two insulating materials, the battery of the present invention intrinsically has double electrical insulation between the live parts and the case. This arrangement minimizes the risk of internal short circuit in the event of a violent impact (impact amplitude greater than the standardized tests). This material is very resistant to wear caused by vibrations (fretting corrosion).

It appears on reading the features described above that the system proposed by the present invention has the following advantages:
A single device provides short-circuit, overcurrent and deep discharge protection at the same time.
Detection of an overcurrent and cut-off without resorting to a current measurement.
Tripping current automatically adapted to the characteristics of the accumulator cells.
No shunt, no magnetic sensor, no heating element.
Disconnection curve similar to a thermomagnetic curve.
The disconnection curve follows the aging of the accumulator cells
Robust load current limitation, without resorting to current measurement.
Ordinary power components (SMD components) due to modularity and reasonable currents.
Balance of currents in power components.
Monitoring of the different quantities by microcontroller.
Communication on a standard data bus, LCD display.
No fine tuning required.
Very low static consumption.
Always-on circuits, no “on” and “stand-by” mode.
A very high level of operational safety (high MTBF).
Use of standard, non-strategic and non-use-specific components for BMS.

It will be easily understood from reading the present application that the features of the present invention, as generally described and illustrated in the figures, can be arranged and designed according to a wide variety of different configurations. Thus, the description of the present invention and the accompanying figures are not intended to limit the scope of the invention, but merely represent selected embodiments.

The person skilled in the art will understand that the technical features of a given embodiment can in fact be combined with features of another embodiment unless the reverse is explicitly mentioned or it is obvious that these features are incompatible. Additionally, the technical features described in a given embodiment may be isolated from the other technical features of that embodiment, unless otherwise specified.

It should be apparent to those skilled in the art that the present invention permits embodiments in many other specific forms without departing from the scope defined by the appended claims; they should be considered by way of illustration and the invention should not be limited to the details given above.

### LIST OF REFERENCE SIGNS

1. Battery pack
2. Block of cell elements in series
20. Cell elements
3. BMS system
4, 4′. Upper PCB (distribution)
5. Middle PCB (BMS)
6. Lower PCB (distribution)
71. Lower bezel
72. Upper bezel
8. Rivets
9. Tongue (thin)
10. Pogo pin
11. Switching device
12. Heater
13. Thermostat/T° C. sensor
14. Balancer
15. Over/under-voltage
16. Power conductor (high current) to the positive terminal
17. Power conductor (high current) to negative terminal
31. Circuit link between the BMS and the switching devices
F. Fuses

1. Battery management system (BMS, 3) for accumulators of a semi-modular element comprising a plurality of lithium cell elements (20) connected in series to form a line, said battery management system for accumulators comprising at least two serial lines connected in parallel constituting the semi-modular element, and at least one detection circuit, characterized in that the detection circuit comprises at least one discharge or short-circuit detection device and at least one device for monitoring the voltage and temperature of a cell element, the detection circuit controlling a circuit breaker device comprising at least one switching device (11) per line, preferably only one per line, and connected on the one hand to the negative or positive pole of each set of cell elements (20) or each battery and on the other hand to the positive or negative terminal, respectively, of the battery, the switching device (11) comprising, for each line, a load breaking device, a discharge breaking device, and electronic components limiting the current at the load, preferably only at the load, and said load breaking device comprising at least two, preferably only two, MOSFETs (M1, M2) per line; a first MOSFET (M1) performing a circuit break in the event of discharge below a threshold or during a short circuit, a second MOSFET (M2) performing a load break in the event of voltage or temperature overshoot of an element of said circuit, the electronic components such as a set of diodes, resistors, capacitors, for example around the second MOSFET (M2), performing a current limitation at the load.

2. Battery management system (BMS, 3) for accumulators of a semi-modular element according to claim 1, characterized in that the first MOSFET (M1) is connected by its source to the negative terminal of a set of cells, this first MOSFET (M1) receives, on its gate, a voltage source (V2) that drives (M1), this source delivering a chosen voltage (for example 6 to 10 V) so that the first MOSFET (M1) is on, a Zener diode (D3) is connected in opposition between the gate and the source of the first MOSFET (M1) and a capacitor (C2) protect the gate of the first MOSFET (M1) from excessively high or high-frequency voltages, and a Zener diode (D1) mounted in opposition between the gate of the first MOSFET (M1) and the drain and in series with a resistor (R3) and a diode (D2) in the forward direction in the drain-to-gate direction, (D1, D2, R3) limiting the switching speed of the first MOSFET (M1) and a circuit consisting of a Schottky diode (D4) limits the load current, this Schottky diode (D4) is mounted in opposition on the drain of the first MOSFET (M1) in the charging direction, and in series with a capacitor C1 and a resistor R1 connected to the positive terminal of the battery to also limit the overvoltage when opening the first MOSFET M1, in parallel on the Schottky diode (D4) a fixed resistor I1 is mounted that is connected on the one hand to the cathode of the diode and on the other hand to the drain of the second MOSFET (M2) whose source is connected to the anode of the Schottky diode (D4), the gate of the second MOSFET (M2) being controlled by an output of the detection circuit to prevent the load.

3. Battery management system (BMS, 3) for accumulators of a semi-modular element according to claim 1, characterized in that the second MOSFET (M2) is connected by its gate to the base of the phototransistor of an optocoupler whose emitter is connected to the source of M2; between these two points, a Zener diode (D5) and a capacitor (C5) are connected by the BMS card; the light-emitting diode of the optocoupler is connected by its cathode to the negative terminal of the battery or of the modular set of cells and receives, on its anode, the command sending a current into the LED in case of detected voltage or temperature overshoot of an element.

4. Battery management system (BMS, 3) for accumulators of a semi-modular element according to claim 1, characterized in that the arrangement of the disconnection circuit associated with the two MOSFETs is interposed between the output pole of a line and the same terminal, of the same polarity (positive or negative), of the battery.

5. Battery management system (BMS, 3) for accumulators of a semi-modular element according to claim 1, characterized in that the BMS is connected to and controls each cell element (20) and each accumulator line of the circuit and monitors the voltage of each cell and each serial line of cells.

6. Battery management system (BMS, 3) for accumulators of a semi-modular element according to one of the preceding claims, wherein the detection circuit comprises one or more of the following functionalities:
Cell voltage balancing;
Detection of excessively low voltage and open circuit
Detection, by a voltage measurement circuit, of short-circuit, deep discharge and overcurrent to trigger the disconnection of a group of cells by opening the circuit
Detection of excessively high voltage of one of the battery cells and opening of the circuit.

7. Battery management system (BMS, 3) for accumulators of a semi-modular element made up of a plurality of lithium cell elements (20) according to claim 4, characterized in that the voltage balancing is performed by a diode OR function connecting each of the cells connected in parallel with the negative polarity of the divider bridge of the short-circuit, deep discharge and overcurrent voltage measurement circuit.

8. Battery management system (BMS, 3) for accumulators of a semi-modular element made up of a plurality of lithium cell elements (20) according to claim 4, characterized in that each cell element of a line is connected to each adjacent cell element of another line by an element constituting a thermal fuse (F), preferably resettable.

9. Battery management system (BMS, 3) for accumulators of a semi-modular element made up of a plurality of lithium cell elements (20) according to claim 1 or 4, characterized in that the detection circuit comprises the following functionalities: integrates temperature monitoring that remains constantly active, even if the battery is “off, by analyzing the temperature in the battery envelope, measured by a probe (13) mounted on the central part of the cards of each module.

10. Battery management system (BMS, 3) for accumulators of a semi-modular element made up of a plurality of lithium cell elements (20) according to claim 1, characterized in that the electronic components of the circuit breaker device limiting the current to the load, preferably only to the load, for regulating the load current comprise a component such as a resistor, which is conductive in one direction, and resistive, like a diode connected in opposition, in the other direction.

11. Battery management system (BMS, 3) for accumulators of a semi-modular element according to claim 1, characterized in that the circuit is arranged in such a way that the charging and discharging switching devices are controlled independently.

12. High-current, semi-modular, series and parallel battery pack (1) consisting of lithium accumulator cells of the same characteristics connected in series to form a line by connections in a given direction S corresponding to the direction of the high currents to obtain the necessary voltage, and intended to be able to be associated in parallel with another line of accumulator cells, said pack comprising a management system (3) according to one of the preceding claims, and characterized in that:
a pair of upper (71) and lower (72) bezels that delimit a set of cylindrical housings with a square or polygonal or circular section defining, in the same direction S, at least one line of cylindrical housings with a square or polygonal section each holding a lithium accumulator cell;
the connections between the accumulator cells of the same line in the direction S are ensured by wide tongues (9) connecting, on each upper or lower face of the module, each pair of adjacent cells connected in series by their poles of opposite polarity in the first direction S, the connecting tongues (9) on one face being offset by one cell on the other face;
the bezels (71, 72) comprise at least two lines of housings parallel to the direction S in which at least two lines of cells are arranged in a direction perpendicular to S and interconnected either by thin tongues acting as a fuse or by resettable fuses (F, FIG. 2), in the direction P perpendicular to the direction S, each fuse (F) connecting two cells belonging to two different parallel lines to make a parallel connection between each cell of two parallel sets of serial cells.

13. High-current battery pack (1) according to claim 11, characterized in that the bezels hold PCBs (printed circuit boards) by the sides at the upper (71) and lower (72) part, which PCBs comprise the electronics and the electrical connections between the electronic components of the management system and the cells of the semi-modular block;
intermediate PCBs (12, 13, FIG. 1) are arranged vertically between the cells in a direction perpendicular to the direction S comprise at least the heating resistors of the semi-modular assembly and these resistors are connected on demand from the management circuit to a power supply;
the PCB part (6) arranged under the cells contributes to recovering the potentials of each of the cells of the semi-modular block to supply them to the voltage management and balancing circuit of the semi-modular block management system.

14. High-current battery pack (1) according to claim 11 or 12, characterized in that resistors are mounted between two contact pads (not shown) on the upper (4, 4′) and/or lower (6) PCBs and the contact with the cells and the tracks of the upper or lower printed circuit boards are made by elastic pins, or conical coil springs, for example, arranged between the cells and the conductive face comprising the contact pads of the printed circuit board, thus avoiding the use of tin solder.

15. High-current, semi-modular battery pack (1) according to one of claims 11 to 13, characterized in that the vertical central board (13) comprises temperature sensors and a thermostat.

16. High-current, semi-modular battery pack (1) according to one of claims 11 to 14, characterized in that the board (5) comprising the management system (BMS, 3) is arranged vertically on the side of the battery pack (1) so as to form a U with the other PCBs (4, 6) of said pack.
